(19) United States
(12) Patent Application Publication
(10) Pub. No.: US 2014/0353880 A1
(43) Pub. Date: Dec. 4, 2014

(54) PROCESS FOR SINTERING THERMOELECTRIC MATERIALS

(71) Applicant: BASF SE, Ludwigshafen (DE)

(72) Inventors: Madalina Andreea Stefan, Ludwigshafen (DE); Frank Haass, Erzhausen (DE)

(73) Assignee: BASF SE, Ludwigshafen (DE)

(21) Appl. No.: 14/463,694

(22) Filed: Aug. 20, 2014

Related U.S. Application Data
(62) Division of application No. 12/843,233, filed on Jul. 26, 2010.

(30) Foreign Application Priority Data
Jul. 27, 2009 (EP) 09166477.1

(51) Int. Cl. H01L 35/34

(52) U.S. Cl. CPC H01L 35/34
USPC 264/434; 264/614

(57) ABSTRACT

The process for producing, processing, sintering, pressing or extruding thermoelectric materials with heat treatment under inert gas or under reduced pressure at temperatures in the range from 100 to 900° C. comprises producing, processing, sintering, pressing or extruding in the presence of oxygen scavengers which form thermodynamically stable oxides in the presence of free oxygen under the production, processing, sintering, pressing or extrusion conditions and hence keep free oxygen away from the thermoelectric material.

This application is a divisional of U.S. application Ser. No. 12/843,233 filed Jul. 26, 2010, pending, and claims the benefit of EP 09166477.1 filed Jul. 27, 2009.

### DESCRIPTION

The invention relates to processes for sintering thermoelectric materials, which lead to thermoelectric materials with improved properties.

Thermoelectric generators and Peltier arrangements as such have been known for some time. p- and n-doped semiconductors which are heated on one side and cooled on the other side transport electrical charges through an external circuit, and electrical work can be performed by a load in the circuit. The efficiency of conversion of heat to electrical energy achieved in this process is limited thermodynamically by the Carnot efficiency. Thus, at a temperature of 1000 K on the hot side and 400 K on the “cold” side, an efficiency of (1000-400): 1000=60% would be possible. However, only efficiencies of up to 6% have been achieved to date.

On the other hand, when a direct current is applied to such an arrangement, heat is transported from one side to the other side. Such a Peltier arrangement works as a heat pump and is therefore suitable for cooling apparatus parts, vehicles or buildings. Heating via the Peltier principle is also more favorable than conventional heating, because more heat is always transported than corresponds to the energy equivalent supplied.

A good review of effects and materials is given, for example, by S. Nolan et al., Recent Developments in Bulk Thermoelectric Materials, MRS Bulletin vol. 31, 2006, 199-206.

At present, thermoelectric generators are used in space probes for generating direct currents, for cathodic corrosion protection of pipelines, for energy supply to light buoys and radio buoys and for operating radios and television sets. The advantage of thermoelectric generators lies in their extreme reliability. For instance, they work irrespective of atmospheric conditions such as atmospheric moisture; there is no fault-prone mass transfer, but rather only charge transfer; the fuel is combusted continuously, and catalytically without a free flame, as a result of which only small amounts of CO, NOₓ and uncombusted fuel are released. It is possible to use any fuels from hydrogen through natural gas, gasoline, kerosene, diesel fuel up to biologically obtained fuels such as rapeseed oil methyl ester.

Thermoelectric energy conversion thus fits extremely flexibly into future requirements such as hydrogen economy or energy generation from renewable energies.

For advantageous functioning of a thermoelectric module, high demands are made not only on the module structure itself, but above all on the thermoelectric material. This must be very substantially homogeneous, crack- and hole-free, of high specific density and of high mechanical stability.

A synthesis of the thermoelectric material is therefore typically followed by a metallurgic processing step in order to achieve these demands.

In the procedure known to the person skilled in the art, the material is therefore first comminuted (for example by grinding) and then compressed again. The compression can be effected by uniaxial or isostatic cold or hot pressing, extrusion, spark plasma sintering, etc. The material is firstly homogenized in the course of comminution, and the further properties required above are achieved in the course of compression.

In the case of cold pressing in particular, another subsequent sintering step is indispensible. During the sintering, further compression and close bonding of the crystal structure take place, such that the sintered bodies at the end have a high density and a high electrical conductivity as desired for thermoelectric materials.

Not all materials, however, can be processed without problems. Especially in the case of oxygen-sensitive materials, particular care should be taken in the course of production. For instance, it is easy for oxygen to be adsorbed on the surface as early as in the course of powder production, which reacts with the material in the course of later thermal treatment (hot pressing, sintering). The following effects are observed:

(1) The formation of surface oxide layers firstly alters the sintering behavior, since the oxide layers behave, for example, like an inert protective layer which can be sintered only with difficulty. This leads to material bodies with relatively low density or powders which are no longer sinterable at the actually desired temperatures.

(2) In addition, these oxide layers can act like an electrical insulator and hence as a barrier. As a result, there is a massive reduction in the electrical conductivity compared to the original bulk material, and the sintered body loses its good thermoelectric properties.

(3) Thirdly, the oxygen can lead to a chemical alteration of the material, not only on the surface but also, according to the chemical nature, in the bulk. This is the case, for example, when the thermoelectric material comprises dopants which react readily and rapidly with oxygen and are withdrawn from the thermoelectric material as the oxide in this way and are no longer available as a dopant.

For this reason, the thermal treatment of thermoelectric materials composed of powders or grains with high surface area constitutes a challenge when an influence of oxygen, for example from the ambient air, cannot be rigorously ruled out.

It is an object of the present invention to provide a process for sintering thermoelectric materials by heat treatment under inert gas or under reduced pressure, which avoids the disadvantages of the existing processes and more particularly very substantially prevents oxygen contact with the thermoelectric material.

The object is achieved in accordance with the invention by a process for producing, processing, sintering, pressing or extruding thermoelectric materials with heat treatment under inert gas or under reduced pressure at temperatures in the range from 100 to 900° C., in which the production, processing, sintering, pressing or extrusion is effected in the presence of oxygen scavengers which form thermodynamically stable oxides in the presence of free oxygen under the production, processing, sintering, pressing or extrusion conditions and hence keep free oxygen away from the thermoelectric material.

It has been found in accordance with the invention that addition of an oxygen scavenger to the thermoelectric material adequately scavenges oxygen still present in the course of sintering, which can no longer develop any harmful effect. During the sintering, the oxygen scavenger rapidly and substantially completely scavenges oxygen residues still present, such that they can no longer react with the thermoelectric material.

Under the sintering conditions, the oxygen scavenger forms thermodynamically stable oxides in the presence of free oxygen and hence keeps free oxygen away from the thermoelectric material. A thermodynamically stable oxide develops, in equilibrium with the unoxidized thermoelectric material, a very low partial oxygen pressure. This means, on the other hand, that the oxides formed do not decompose again to a significant degree at sintering temperatures. The oxygen scavenger reacts by oxidation reaction with the oxygen still present in the gas space in the course of sintering and binds it, such that the oxygen cannot react with the thermoelectric material. The oxygen scavenger is more readily oxidizable than the thermoelectric material, and at lower temperatures.

The oxygen scavengers used are inorganic materials, preferably metals, metal alloys and semimetals, and alloys thereof. Typical examples are titanium, zirconium, hafnium, silicon, aluminum, vanadium, scandium, yttrium, rare earth metals (for example lanthanum or cerium), lithium, sodium, potassium, magnesium, calcium, strontium, barium, manganese, iron, cobalt, nickel, copper, zinc, cadmium, but also nonmetals such as phosphorus, graphite and mixtures thereof.

Gaseous oxygen scavengers may be selected from H₂, CO, CO/CO₂ mixtures, H₂/H₂O mixtures or inert gas/H₂ mixtures.

Oxygen scavengers may also be selected from hydrides, carbonyls, lower valency oxides, sulfides, phosphides, of metals, preferably above metals, sulfur or phosphorus containing compounds generally, sulfur, phosphorus and mixtures thereof. Lower valency oxides are those oxides which can be further oxidized to higher valency oxides in the presence of free oxygen.

The oxygen scavenger used may be a material which comprises no chemical elements of the thermoelectric material. It may also be a dopant material.

The amount of the oxygen scavenger for use can be set according to the practical requirements. They are guided by the remaining oxygen content in the inert gas in the course of sintering and by the oxygen affinity of the constituents of the thermoelectric materials. In general, based on the amount of the thermoelectric material, under 25% by weight, preferably 0.05 to 15% by weight, especially 0.05 to 1% by weight of oxygen scavenger is used.

The surface of the solid oxygen scavengers can be pretreated in order to enhance the efficacy thereof, for example by roughening, mechanical, chemical or electrochemical removal of an oxide layer already present, or by a mechanical, chemical or electrochemical activation of the surface.

The solid oxygen scavenger can be used in any desired form, for example as a powder, wire, sheet, ribbon, lumps, pellets, shaped body, sponge or mesh, or supported on an inert material.

The thermoelectric material can be used for sintering in any desired suitable form. Frequently, a green body is sintered, but it is also possible to sinter a powder or granule of the thermoelectric material under pressure with shaping.

In one embodiment of the invention, a green body composed of a thermoelectric material which has been subjected to shaping is sintered in direct contact with the oxygen scavenger.

In a further embodiment of the invention, the green body composed of a thermoelectric material which has been subjected to shaping and the oxygen scavenger are spatially separate from one another in the course of sintering, but are connected via a common gas space.

In a further embodiment of the invention, the sintering is effected under pressure with shaping of a powder of the thermoelectric material. The sintering under pressure can be effected as hot pressing, isostatic pressing or hot pressing, or spark plasma sintering. In the course of this procedure, the oxygen scavenger in the compression mold may be arranged in contact with the thermoelectric material or may be pressed in the form of a sandwich with the powder of the thermoelectric material.

It is also possible to perform the sintering directly in an extrusion.

The inventive sintering operations can produce any desired shaped bodies of the thermoelectric material. Preference is given to sintering to directly produce thermoelectric material legs.

In the course of production or processing, for example, powders, granules or melts of the thermoelectric materials or components thereof can be used. They are not in direct contact with the oxygen scavenger, which may be connected to them, for example, via a common gas space.

The thermoelectric material used in the process according to the invention is not subject to any restrictions. The materials may be p- or n-conductive and have appropriate dopants. The underlying thermoelectric material is preferably selected from PbTe, Bi₂Te₃, Zintl phases, skutterudites, clathrates and zinc antimonides, Heusler compounds, silicides, oxides or mixtures thereof. Suitable materials are mentioned, for example, in the document by S. Nolan cited at the outset.

The thermoelectric materials are generally produced by reactive grinding or preferably by co-melting and reaction of mixtures of the particular element constituents or alloys thereof, these steps being performable in the presence of oxygen scavengers.

The thermoelectric material (green body, leg, powder, granule) is sintered at a temperature of generally at least 100° C., preferably at least 200° C., lower than the melting point of the resulting semiconductor material in the presence of the oxygen scavengers. Typically, the sintering temperature is 350 to 900° C., preferably 500 to 800° C. It is also possible to perform spark plasma sintering (SPS) or microwave sintering.

The sintering is performed over a period of preferably at least 0.5 hour. The sintering time is typically 1 to 24 hours. In one embodiment of the present invention, the sintering is performed at a temperature which is 100 to 500° C. lower than the melting temperature of the resulting semiconductor material. The sintering can be performed under a protective gas atmosphere, for example of argon, hydrogen or inert gas/hydrogen.

The pressed parts are thus sintered preferably to 90 to 100% of their theoretical bulk density.

A preferred embodiment overall is thus a process which is characterized by the following process steps:
(1) co-melting of mixtures of the particular element constituents, or alloys thereof, of the thermoelectric material;
(2) comminuting the material obtained in process step (1);
(3) pressing the material obtained in process step (2) to give shaped bodies and
(4) sintering the shaped bodies obtained in process step (3) with oxygen scavengers.

There is no restriction on the pretreatment of the material and the powder production. The material for the sintering can be produced, for example, by grinding a fusion product, or else directly in powder form by rapid solidification (melt spinning) or corresponding synthesis methods (precipitation, spraying, etc.). The powder is precompressed to the green body by techniques known for that purpose to the person skilled in the art. It is preferred not to already compress the green body close to 100%, in order still to enable gas exchange with the environment during the sintering. The actual compression is not effected until the sintering step.

For the sintering according to the present invention, there are several options.

The oxygen scavenger can be directly sealed into an ampoule together with the green body. In this case, the oxygen scavenger may either be in direct contact with the green body, or spatially separate. The direct contact can be effected, for example, by winding wire around it, placing it onto a small mesh, embedding it into a powder bed, etc.

The spatial separation can be achieved by a dividing wall (for example quartz wool), but also in an ampoule with a plurality of compartments (for example in dumbbell form). Several compartments have the advantage that the oxygen scavenger and the material can also be exposed to different temperature levels in a multizone oven, if desired and necessary.

The ampoule can be manufactured, for example, from quartz glass, but also directly from the material of the oxygen scavenger. The sintering should then be effected in the furnace under inert conditions in order to prevent oxidation of the outside or permeation of oxygen through the vessel wall. It is also possible to subsequently coat the ampoule of the scavenger material on the outside with an inert layer, or conversely to introduce a layer of the scavenger material onto the inside of the ampoule.

It is also possible to use the oxygen scavenger in an open sintering operation. An open sintering operation can be effected, for example, in a conventional furnace in a graphite, quartz or metal crucible. Optionally, the crucible material itself may also serve as the oxygen scavenger. The oxygen scavenger can simply be added to the green body in the crucible, either in bulk form (wire, mesh, etc.), or as a powder. The green body can then be placed onto the powder, or be present directly within the powder. Optionally, the oxygen scavenger in powder form can also be “diluted” by an additive such as graphite, quartz sand, inert ceramic or the like.

Alternatively, it is additionally possible to place the oxygen scavenger spatially upstream of the green body in the gas stream. The sintering can be performed under an inert gas stream (He, Ar, N₂), in which case the reducing action of the oxygen scavenger can be supported by a reducing gas (H₂, CO) which is added to the inert gas stream or completely replaces it. Alternatively, it is possible to sinter under reduced pressure. The sintering can be brought about by electrical, inductive, microwave or combustion heating.

In the case of sintering under pressure too (hot pressing, spark plasma sintering), it is possible to use an oxygen scavenger. For this purpose, for example, the embodiments which follow are conceivable.

First, it is possible to integrate oxygen scavenger materials into the shell of the compression die, instead of using a pure graphite or pure steel die. Coating of the inside of the compression die with the oxygen scavenger is also possible. The same precautions can also be taken in the course of production or processing of the thermoelectric materials.

In addition, co-compaction of the thermoelectric material powder and of the oxygen scavenger in the form of a sandwich is possible. The thermoelectric material powder is layered onto the oxygen scavenger, and the two are compressed together by hot pressing or SPS. The oxygen scavenger may likewise be used as a powder but also as a precompressed or bulk shaped body. The same applies to the thermoelectric material, which may likewise be precompacted to a green body before the hot pressing or SPS step. After the compaction, oxygen scavenger and material body are mechanically separated from one another (cutting, sawing, etc.; the corresponding processes are known to those skilled in the art).

Extrusion of the materials to dense shaped bodies is also possible. In the case of thermoelectric materials, this is typically done at elevated temperature and can be performed as described in WO 01/17034; see also U.S. Pat. No. 3,220,199 and U.S. Pat. No. 4,161,111. It is possible here to use an oxygen scavenger by means of a suitable capsule material in the manner of an encapsulated extrusion (the underlying process is known to the person skilled in the art), in which case either the entire capsule can be produced from the material in question, which is then inertized on the outside by an additional coating, or the capsule is coated on the inside with the oxygen scavenger material.

An analogous capsule process is also applied in isostatic hot pressing.

The compaction by hot pressing, SPS or extrusion, etc., may be followed by a further sintering step. For this step, the same options and conditions apply as already described above for the cold pressing/sintering.

The sintered bodies may either already be produced directly in the leg geometry needed for the thermoelectric module, or else legs can be cut out of the sintered bodies in the required geometry. This can be done by methods known to those skilled in the art.

The invention also relates to a process for increasing the long-term stability of thermoelectric legs, in which the legs are operated in a thermoelectric module in the presence of oxygen scavengers.

The invention is illustrated in detail by the examples which follow.

### EXAMPLES

### Example 1

n-doped PbTe bulk material was comminuted and pressed to a compact pellet at 30 kN under air for 60 seconds. The pellet was removed from the press and Ti wire of diameter 0.25 mm and length 3 cm was wound around it, and they were sintered in a closed quartz ampoule at 600° C. for 72 hours.

After the sintering, the power factor was determined at 300° C. For the body around which Ti wire had been wound, a power factor of 21.5 μW/K² cm was found.

When the Ti wire was dispensed with for comparison, a power factor of 0.45 μW/K² cm was found.

It thus becomes clear that the sintering process according to the invention leads to significantly improved power factors.

### Example 2

Doped PbTe bulk material was comminuted and milled and mixed with 0.1 % by weight TiH₂. The mixture was pressed to a compact pill under a force of 15 kN for one second. The pill was taken from the cold press and sintered in an ampule at 700° C. for 3 hours.

| | Seebeck (μV/K) | Electrical conductivity |
|---|---|---|
| | 250° C. | (S/cm) at |
| Test body | measurement | room temperature |
| Molten body | −135.88 | 2284.3 |
| Cold pressed/sintered body | −139.96 | 2160.9 |

1-15. (canceled)

16. A process for producing, processing, or sintering a thermoelectric material, the process comprising:
producing, processing, or sintering a thermoelectric material with heat treatment under an inert gas or reduced pressure, at temperatures in a range of from 100 to 900° C., in the presence of an oxygen scavenger which forms a thermodynamically stable oxide in the presence of free oxygen under production, processing, sintering, pressing, or extrusion conditions, thereby keeping free oxygen away from the thermoelectric material,
wherein the sintering is carried out such that a green body comprising the thermoelectric material which has been subjected to shaping and the oxygen scavenger are spatially separate from one another in the course of sintering, but are connected via a common gas space; and
wherein in the course of producing or processing the thermoelectric material is not in direct conduct with the oxygen scavenger.

17. The process of claim 16, wherein the oxygen scavenger comprises Ti, Zr, Hf, Si, Al, V, Sc, Y, La, Ce, Pr, Nd, Pm, Sm, Eu, Gd, Tb, Dy, Ho, Er, Tm, Yb, Lu, Li, Na, K, Mg, Ca, Sr, Ba, Mn, Fe, Co, Ni, Cu, Zn, Cd, P, or a mixture thereof.

18. The process of claim 16, wherein the oxygen scavenger comprises H₂, CO, a CO/CO₂ mixture, an H₂/H₂O mixture, or an inert gas/H₂ mixture.

19. The process of claim 16, wherein the oxygen scavenger comprises a metal hydride, metal carbonyl, lower valency metal oxide, metal sulfide, metal phosphide, a sulfur comprising compound, a phosphorus comprising compound, sulfur, phosphorus, or a mixture thereof.

20. The process of claim 16, wherein the thermoelectric material comprises PbTe, Bi₂Te₃, a Zintl phase, a skutterudite, a clathrate, a zinc antimonide, a Heusler compound, a silicide, an oxide, or a mixture thereof.

21. The process of claim 16, wherein the sintering is carried out such that a green body comprising the thermoelectric material which has been subjected to shaping is sintered in direct contact with the oxygen scavenger.

22. The process of claim 16, wherein the sintering is carried out and is effected under pressure with shaping of a powder of the thermoelectric material.

23. The process of claim 22, wherein the sintering under pressure is effected as hot pressing.

24. The process of claim 22, wherein the oxygen scavenger is arranged in a compression mold in contact with the thermoelectric material.

25. The process of claim 22, wherein the sintering under pressure is performed as an extrusion.

26. The process of claim 16, wherein the sintering directly produces a thermoelectric material leg.

27. The process of claim 16, wherein the solid oxygen scavenger is used in the form of a powder, wire, sheet, ribbon, granule, shaped body, mesh, or in pellet form.

28. The process of claim 22, wherein the sintering under pressure is effected as isostatic hot pressing.

29. The process of claim 22, wherein the sintering under pressure is effected as spark plasma sintering.

30. The process of claim 22, wherein the oxygen scavenger is pressed in the form of a sandwich with the powder of the thermoelectric material.

31. The process of claim 16, wherein under 25% by weight of the oxygen scavenger is present, based on an amount of the thermoelectric material.

32. The process of claim 16, wherein from 0.05 to 15% by weight of the oxygen scavenger is present, based on an amount of the thermoelectric material.

33. The process of claim 16, wherein from 0.05 to less than 1% by weight of the oxygen scavenger is present, based on an amount of the thermoelectric material.

34. The process of claim 16, wherein the oxygen scavenger comprises Ti.
